(19) United States
(12) Patent Application Publication
(10) Pub. No.: US 2025/0119115 A1
(43) Pub. Date: Apr. 10, 2025

(54) Bulk Acoustic Wave Resonant Deviceresonator and Method For Manufacturing Same

(71) Applicant: Wuhan MEMSonics Technologies Co., Ltd., Wuhan (CN)

(72) Inventors: Jinhao DAI, Wuhan (CN); Jinxian ZHANG, Wuhan (CN); Tingting YANG, Wuhan (CN); Si CHEN, Wuhan (CN); Hanlong YUAN, Wuhan (CN); Xin TONG, Wuhan (CN); Liangyu LU, Wuhan (CN); Guoqiang WU, Wuhan (CN); Jian WANG, Singapore (SG); Bowoon SOON, Singapore (SG); Chengliang SUN, Wuhan (CN)

(21) Appl. No.: 18/668,712

(22) Filed: May 20, 2024

(30) Foreign Application Priority Data
Oct. 9, 2023 (CN) 202311303069.7

(51) Int. Cl. H03H 9/205; H03H 3/02; H03H 9/13

(52) U.S. Cl. CPC H03H 9/205; H03H 3/02; H03H 9/13

(57) ABSTRACT

The present application discloses a bulk acoustic wave resonator and a method for manufacturing the same. The bulk acoustic wave resonator includes a substrate and a plurality of resonance assemblies arranged on the substrate, each of the plurality of resonance assemblies includes a bottom electrode, a piezoelectric layer, and a top electrode which are arranged on the substrate in sequence; the plurality of resonance assemblies are connected in sequence to form a connecting ring; the top electrode of one resonance assembly in two adjacent resonance assemblies is connected to the bottom electrode of the other resonance assembly in the two adjacent resonance assemblies, and the top electrodes of two target resonance assemblies spaced apart by one resonance assembly are connected to each other to transmit an input signal; and the bottom electrodes of the two target resonance assemblies are connected to each other to transmit an output signal.

### CROSS-REFERENCE TO RELATED APPLICATION

This application is filed based upon and claims priority to Chinese Patent Application No. 202311303069.7 filed on Oct. 9, 2023, the contents of which are hereby incorporated by reference in its entirety.

### TECHNICAL FIELD

The present application relates to the technical field of resonators, and in particular, to a bulk acoustic wave resonator and a method for manufacturing the same.

### BACKGROUND

A bulk acoustic wave filter is composed of a plurality of bulk acoustic wave resonators connected in series or in parallel. The bulk acoustic wave resonator is manufactured by longitudinal resonance of a piezoelectric thin film in a thickness direction. The bulk acoustic wave resonator has become a feasible alternative to a surface acoustic wave device and a quartz crystal resonator in mobile communications, high-speed serial data applications, and other aspects. Therefore, a radio frequency front-end thin film bulk acoustic wave filter/duplexer has superior filtering characteristics, such as low insertion loss, steep transition band, high anti-static discharge ability, and the like.

In order to enhance second harmonics suppression of the bulk acoustic wave filter, in the related technology, resonance assemblies that are in reverse series connection or in reverse parallel connection are designed in a circuit. The reverse series connection weakens the nonlinear effect of the assemblies by reducing the energy density. Specifically, in order to satisfy the transmission characteristics of the resonance assemblies, the reverse series connection requires doubling an area of active regions. One resonator occupies the area of two active regions, so that one resonance assembly in reverse series connection occupies an area that is four times the area occupied by the original resonator, resulting in a large area occupied by the resonance assemblies that are in reverse series connection. The reverse parallel connection weakens the nonlinear effect of the assemblies by the principle of phase cancellation. Specifically, two resonators reduce the area of the active region of the resonance assembly by half. Although this method does not enlarge the area, its efficiency of second harmonics suppression is low, so that this method may not meet a requirement of the filter for a depth of second harmonics suppression.

### SUMMARY

The present application provides a bulk acoustic wave resonator and a method for manufacturing the same.

One aspect of an embodiment of the present application provides a bulk acoustic wave resonator, including a substrate and a plurality of resonance assemblies arranged on the substrate; each of the plurality of resonance assemblies includes a bottom electrode, a piezoelectric layer, and a top electrode which are arranged on the substrate in sequence; the plurality of resonance assemblies are connected in sequence to form a connecting ring; the top electrode of one resonance assembly in two adjacent resonance assemblies is connected to the bottom electrode of the other resonance assembly in the two adjacent resonance assemblies; two resonance assemblies spaced apart by one resonance assembly are two target resonance assemblies; top electrodes of the two target resonance assemblies are connected to each other to transmit an input signal; and bottom electrodes of the two target resonance assemblies are connected to each other to transmit an output signal.

As an implementation, the bulk acoustic wave resonator includes four resonance assemblies; and the four resonance assemblies are connected in sequence through top electrodes and bottom electrodes to form the connecting ring.

As an implementation, the four resonance assemblies are arranged in a determinant manner on the substrate.

As an implementation, an interconnection region is formed between every two adjacent resonance assemblies, and the top electrode of one resonance assembly in the every two adjacent resonance assemblies and the bottom electrode of the other resonance assembly in the every two adjacent resonance assemblies are connected in the interconnection region.

As an implementation, a plurality of piezoelectric layers are connected in interconnection regions; at least one through groove is formed in the piezoelectric layer in each interconnection region to form a connection region; and at least one of the following is satisfied: the bottom electrode extend into the through groove, so as to be connected to the top electrode, and the top electrode extend into the through groove, so as to be connected to the bottom electrode.

As an implementation, a cross section of each through groove in a stacking direction is in one shape of a polygon, a circle, and a pattern formed by combining a plurality of curved edges.

As an implementation, a plurality of piezoelectric layers are separated in interconnection regions, and at least one of the following is satisfied: the bottom electrode extend to the interconnection region, so as to be connected to the top electrode, and the top electrode extend to the interconnection region, so as to be connected to the bottom electrode.

As an implementation, the top electrodes of the two target resonance assemblies are led out to one side of the determinant, and the bottom electrodes of the two target resonance assemblies are connected and led out to an opposite side to the one side of the determinant.

As an implementation, a seed layer is further arranged on the substrate, and the plurality of resonance assemblies are arranged on the substrate through the seed layer.

Another aspect of an embodiment of the present application provides a method for manufacturing a bulk acoustic wave resonance assembly, which is used for manufacturing the bulk acoustic wave resonance assembly described above, including: a substrate is provided, and a metal material is deposited on the substrate to form a bottom electrode layer; the bottom electrode layer is etched to form a plurality of bottom electrodes, and a first trench is provided between every two adjacent bottom electrodes to separate the plurality of bottom electrodes; a piezoelectric material is deposited on an etched bottom electrode layer to form a piezoelectric base layer; the piezoelectric base layer is etched to respectively form a plurality of piezoelectric layers on the plurality of bottom electrodes, and a second trench is provided between every two adjacent piezoelectric layers to separate the plurality of piezoelectric layers; a metal material is deposited on an etched piezoelectric base layer to form a top electrode layer, and the top electrode layer fills first trenches and second trenches; the top electrode layer is etched to correspondingly form a plurality of top electrodes on the plurality of piezoelectric layers, and each top electrode is connected to the bottom electrode adjacent to the top electrode through the metal material in the first trenches and the second trenches; and the top electrodes of two target resonance assemblies that are spaced apart by one resonance assembly are connected to lead out an input end, and the bottom electrodes of the two target resonance assemblies are connected to lead out an output end.

### BRIEF DESCRIPTION OF THE DRAWINGS

For clearer descriptions of the technical solutions of the embodiments of the present application, the drawings required to be used in the embodiments are briefly introduced below. It should be understood that the drawings below are only some embodiments of the present application. Therefore, the embodiments shall not be regarded as limitations on the scope. A person of ordinary skill in the art may also obtain other relevant drawings according to these drawings without creative work.

FIG. 1 is a schematic structural diagram of a bulk acoustic wave resonator according to an embodiment of present application;

FIG. 2 is a circuit diagram of a bulk acoustic wave resonator according to an embodiment of present application;

FIG. 3 is a cross-sectional view of FIG. 1 along A-A;

FIG. 4 is a flowchart of a method for manufacturing a bulk acoustic wave resonator according to an embodiment of the present application; and

FIG. 5 and FIG. 6 are schematic structural diagrams of a method for manufacturing a bulk acoustic wave resonator according to an embodiment of the present application after some process steps.

### DETAILED DESCRIPTION OF THE EMBODIMENTS

In order to make the objectives, technical solutions, and advantages of the embodiments of the present application clearer, the technical solutions in the embodiments of the present application are clearly and completely described below with reference to the accompanying drawings in the embodiments of the present application. Apparently, the described embodiments are merely some rather than all of the embodiments of the present application. Assemblies of the embodiments of the present application commonly described and shown in the accompanying drawings here may be arranged and designed in a variety of different configurations.

Accordingly, the following detailed descriptions of the embodiments of the present application provided in the accompanying drawings are not intended to limit the scope of the claimed present application, but merely represents selected embodiments of the present application. All other embodiments obtained by a person of ordinary skill in the art based on the embodiments of the present application without making creative efforts shall fall within the protection scope of the present application.

It should be noted that similar reference numerals and letters indicate similar items in the following drawings. Therefore, once a certain item is defined in one drawing, it is unnecessary to further define and explain it in the subsequent drawings.

In addition, the terms “first”, “second”, “third”, and the like are only for the purpose of description, and may not be understood as indicating or implying the relative importance.

In the description of the present application, it should be noted that unless otherwise specified and limited, the terms “arrange”, “mount”, “connect”, and “connection” should be broadly understood. For example, it may be a fixed connection, detachable connection, integrated connection, mechanical connection, electrical connection, direct connection, indirect connection via an intermediate element, or internal communication between two elements. A person of ordinary skill in the art may understand the specific meanings of the above terms in the present application according to specific situations.

A bulk acoustic wave resonator has the characteristics of small size, high working frequency, low power consumption, high quality factor, and compatibility with a Complementary Metal-Oxide-Semiconductor Transistor (CMOS) technology. At present, the bulk acoustic wave resonator is more and more widely applied to the field of communication devices. At least two bulk acoustic wave resonators may be electrically connected to form a bulk acoustic wave filter.

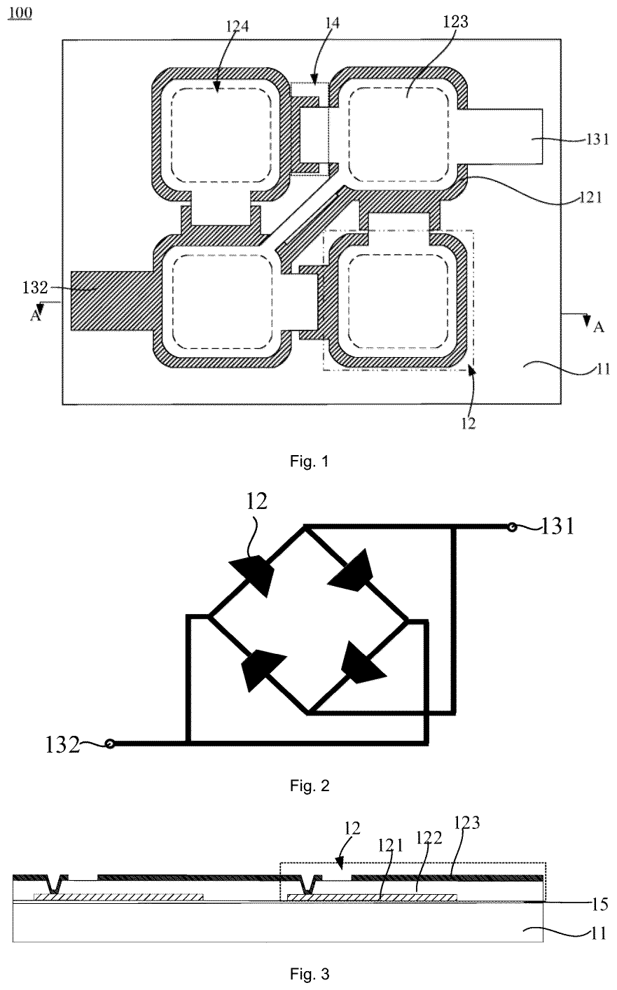

An embodiment of the present application provides a bulk acoustic wave resonator 100, as shown in FIG. 1, FIG. 2, and FIG. 3, the bulk acoustic wave resonator includes a substrate 11 and a plurality of resonance assemblies 12 arranged on the substrate 11; each of the plurality of resonance assemblies 12 includes a bottom electrode 121, a piezoelectric layer 122, and a top electrode 123 which are arranged on the substrate 11 in sequence; the plurality of resonance assemblies 12 are connected in sequence to form a connecting ring; the top electrode 123 of one resonance assembly 12 in two adjacent resonance assemblies 12 is connected to the bottom electrode 121 of the other resonance assembly 12 in the two adjacent resonance assemblies 12; two resonance assemblies 12 spaced apart by one resonance assembly 12 are two target resonance assemblies; top electrodes 123 of the two target resonance assemblies are connected to each other to transmit an input signal; and bottom electrodes 121 of the two target resonance assemblies are connected to each other to transmit an output signal.

The plurality of resonance assemblies 12 provided by this embodiment of the present application are configured to form the bulk acoustic wave resonator 100. Specifically, the input signal is input from the top electrodes 123 of the two target resonance assemblies spaced apart by one resonance assembly 12 to the bulk acoustic wave resonator 100. In a circuit, the input signal is applied between the top electrode 123 of a first resonance assembly 12 in two adjacent resonance assemblies 12 and the bottom electrode 121 of a second resonance assembly 12 in the two adjacent resonance assemblies 12; and the bottom electrode 121 of the first resonance assembly 12 is connected to the top electrode 123 of the second resonance assembly 12. The two resonance assemblies 12 are in reverse parallel connection to suppress second harmonics. Similarly, the bottom electrodes 121 of the two target resonance assemblies are connected to connect the output signal. In the circuit, the output signal is applied between the top electrode 123 of a second resonance assembly 12 in two adjacent resonance assemblies 12 and the bottom electrode 121 of a third resonance assembly 12 in the two adjacent resonance assemblies 12, and the bottom electrode 121 of the second resonance assembly 12 is connected to the top electrode 123 of the third resonance assembly 12. The two resonance assemblies 12 are in reverse parallel connection to suppress the second harmonics again, thereby improving the effect of second harmonics suppression.

In addition, among the plurality of resonance assemblies 12 in this embodiment of the present application, the top electrode 123 of one resonance assembly 12 in two adjacent resonance assemblies 12 is connected to the bottom electrode 121 of the other resonance assembly 12 in the two adjacent resonance assemblies 12. The top electrode 123 of the one resonance assembly is connected to the bottom electrode 121 of the other resonance assembly, so that the plurality of resonance assemblies 12 are in reverse parallel connection. According to the transmission characteristics of the resonance assemblies 12, the plurality of resonance assemblies 12 in the reverse parallel connection occupy an area of one resonator, so that the area occupied by the bulk acoustic wave resonator 100 provided by the present application is not enlarged.

Among the plurality of resonance assemblies 12, each resonance assembly 12 includes a bottom electrode 121, a piezoelectric layer 122, and a top electrode 123 which are arranged on the substrate 11 in sequence. A region where the bottom electrode 121, the piezoelectric layer 122, and the top electrode 123 overlap is a resonance region 124 (as shown by the dashed lines in FIG. 1). A specific shape of the resonance region 124 is not specified in this embodiment of the present application, and may be a regular polygon, an irregular polygon, a circle, a closed pattern formed by a plurality of curved edges, or the like. Exemplarily, as shown in FIG. 1, the shape of the resonance region 124 is the closed shape formed by the plurality of curved edges. In addition, in order to improve the vibration efficiency of the resonance region 124, a cavity may be arranged in the substrate 11 corresponding to the resonance region 124, and the bottom electrode 121 is arranged at a top of the cavity as a covering surface of the cavity.

Specifically, a specific type of the bulk acoustic wave device is not limited in this embodiment of the present application. The bulk acoustic wave device may be a filter formed by a plurality of resonance assemblies 12, a duplexer formed by two filters, a multiplexer formed by a plurality of duplexers, or another bulk acoustic wave device.

The bulk acoustic wave resonator 100 provided by the present application includes a substrate 11 and a plurality of resonance assemblies 12 arranged on the substrate 11; each of the plurality of resonance assemblies 12 includes a bottom electrode 121, a piezoelectric layer 122, and a top electrode 123 which are arranged on the substrate 11 in sequence; the plurality of resonance assemblies 12 are connected in sequence to form a connecting ring; and the top electrode 123 of one resonance assembly 12 in two adjacent resonance assemblies 12 is connected to the bottom electrode 121 of the other resonance assembly 12 in the two adjacent resonance assemblies 12. The top electrode 123 of one resonance assembly is connected to the bottom electrode 121 of the other resonance assembly, so that the plurality of resonance assemblies 12 are in reverse parallel connection. According to the transmission characteristics of the resonance assemblies 12, the plurality of resonance assemblies 12 in the reverse parallel connection occupy an area of one resonator, so that the area occupied by the bulk acoustic wave resonator 100 provided by the present application is not enlarged. The top electrodes 123 of two target resonance assemblies spaced apart by one resonance assembly 12 are connected to each other to transmit an input signal. In a circuit, the input signal is applied between the top electrode 123 of a first resonance assembly 12 in two adjacent resonance assemblies 12 and the bottom electrode 121 of a second resonance assembly 12 in the two adjacent resonance assemblies 12; and the bottom electrode 121 of the first resonance assembly 12 is connected to the top electrode 123 of the second resonance assembly 12. The two resonance assemblies 12 are in reverse parallel connection to suppress second harmonics. Similarly, the bottom electrodes 121 of the two target resonance assemblies are connected to each other to transmit an output signal. In the circuit, the output signal is applied between the top electrode 123 of a second resonance assembly 12 in two adjacent resonance assemblies 12 and the bottom electrode 121 of a third resonance assembly 12 in the in two adjacent resonance assemblies 12, and the bottom electrode 121 of the second resonance assembly 12 is connected to the top electrode 123 of the third resonance assembly 12. The two resonance assemblies 12 are in reverse parallel connection to suppress the second harmonics again, thereby improving the effect of second harmonics suppression. Therefore, the bulk acoustic wave resonator 100 provided by the embodiments of the present application may improve the effect of second harmonics suppression on the basis of not enlarging an area occupied by the bulk acoustic wave resonator 100.

In some embodiments, as shown in FIG. 1, FIG. 2, and FIG. 3, the bulk acoustic wave resonator includes four resonance assemblies 12; and the four resonance assemblies 12 are connected in sequence through top electrodes 123 and bottom electrodes 121 to form the connecting ring. That is, among the four resonance assemblies, the top electrode of any one resonance assembly is connected to the bottom electrode of at least one adjacent resonance assembly, and the bottom electrode of the one resonance assembly is connected to the top electrode of the at least one adjacent resonance assembly, so that the four resonance assemblies are connected to form the connecting ring.

When the bulk acoustic wave resonant device includes four resonance assemblies 12, the four resonance assemblies 12 are connected in sequence to form the connecting ring. The top electrode 123 of one of two adjacent resonance assemblies 12 is connected to the bottom electrode 121 of the other resonance assembly, so as to form the connecting ring as shown in FIG. 2. Assuming that the resonance assembly 12 in the top left corner of FIG. 1 is a first resonance assembly 12, and the other resonance assemblies 12 in a direction of the connecting ring are a second resonance assembly 12, a third resonance assembly 12, and a fourth resonance assembly 12 in sequence. The first resonance assembly 12 is used as a middle resonance assembly 12, and the second resonance assembly 12 and the fourth resonance assembly 12 are arranged on two sides of the first resonance assembly 12 in a spacing manner, that is, the second resonance assembly 12 and the fourth resonance assembly 12 are used as the target resonance assemblies, that is, the top electrodes 123 of the second resonance assembly 12 and the fourth resonance assembly 12 are connected and led out to form an input end 131, which is configured to connect the input signal; and the bottom electrodes 121 of the second resonance assembly 12 and the fourth resonance assembly 12 are connected and led out to form an output end 132, which is configured to connect the output signal.

When the bulk acoustic wave resonator includes four resonance assemblies 12, the four resonance assemblies 12 form a balancing bridge structure. Reverse parallel connection structures are respectively formed on two sides of the input end 131. The two reverse parallel connection structures may suppress the second harmonics, thereby improving the depth of suppressing the second harmonics and improving the effect of second harmonics suppression. Similarly, reverse parallel connection structures are respectively formed on two sides of the output end 132. The two reverse parallel connection structures may suppress the second harmonics, thereby improving the depth of suppressing the second harmonics and improving the effect of second harmonics suppression.

It should be noted that each resonance assembly 12 in FIG. 2 is represented by a trapezoid, where an upper bottom (the shorter bottom) of the trapezoid is the top electrode 123 of the resonance assembly 12, and a lower bottom (the longer bottom) of the trapezoid is the bottom electrode 121 of the resonance assembly 12.

In an implementation of this embodiment of the present application, as shown in FIG. 1, the four resonance assemblies 12 are arranged in a determinant manner on the substrate 11.

The four resonance assemblies 12 are distributed in the determinant manner on the substrate 11, which means that the four resonance assemblies 12 are arranged in two rows and two columns, so that the arrangement of the resonance assemblies 12 is more regular and occupies a small volume. In addition, the four resonance assemblies 12 are arranged in the determinant manner, so that the four resonance assemblies 12 are relatively close, facilitating the connection between the bottom electrodes 121 and top electrodes 123 of two adjacent resonance assemblies 12.

As shown in FIG. 1, among the four resonance assemblies, the two target resonance assemblies are centrosymmetric. That is, the second resonance assembly 12 and the fourth resonance assembly 12 are centrosymmetric.

In some embodiments, as shown in FIG. 1, an interconnection region 14 is formed between every two adjacent resonance assemblies 12, and the top electrode 123 of one resonance assembly 12 in the every two adjacent resonance assemblies 12 and the bottom electrode 121 of the other resonance assembly 12 in the every two adjacent resonance assemblies 12 are connected in the interconnection region 14, that is, the top electrode 123 and the bottom electrode 121 are connected by a connection line in the interconnection region 14.

The top electrodes 123 and the bottom electrodes 121 are connected in the interconnection regions 14. The interconnection regions have a large area. Therefore, the connection line between the bottom electrodes 121 and the top electrodes 123 has a large connection width, which avoids additional loss caused by unstable connection between two resonance assemblies 12.

In an implementation of this embodiment of the present application, as shown in FIG. 1, a plurality of piezoelectric layers 122 are connected in the interconnection regions 14, that is, the plurality of piezoelectric layers 122 are connected by connection lines in the interconnection regions 14; at least one through groove is formed in the piezoelectric layers 122 in each interconnection region to form a connection region; the bottom electrode 121 extend into the through groove, so as to be connected to the top electrode 123, and/or, the top electrode 123 extend into the through groove, so as to be connected to the bottom electrode 121.

Each through groove is filled with air. The acoustic impedance of the piezoelectric layers 122 is different from that of the air, so that an acoustical reflection structure is formed by the through grooves on outer sides of the piezoelectric layers 122. This may reflect sound waves generated in the piezoelectric layers 122 back into the piezoelectric layers 122, avoiding leakage of the sound waves from edges of the piezoelectric layers 122, thereby improving the quality factor of the bulk acoustic wave resonator 100.

In some embodiments, a cross section of each through groove in a stacking direction is in one shape of a polygon, a circle, or a pattern formed by combining a plurality of curved edges.

The polygon includes a regular polygon and an irregular polygon. By the arrangement of the through grooves in various shapes, the convenience of arrangement of through grooves may be improved or the leakage of the sound waves may be further reduced. Specifically, when the cross section of each through groove in the stacking direction is in the shape of the regular polygon, the through groove is easy to manufacture. When the cross section of the through groove in the stacking direction is in the shape of the irregular polygon, the circle, or the pattern formed by combining the plurality of curved edges, the reflection effect on the sound waves is enhanced, thereby further improving the quality factor of the bulk acoustic wave resonator 100.

In an implementation of this embodiment of the present application, a plurality of piezoelectric layers 122 are separated in interconnection regions 14; the bottom electrodes 121 extend to the interconnection regions 14, that is, the connection lines connected to the bottom electrodes 121 extend to the interconnection regions 14, so as to be connected to the top electrodes 123, and/or, the top electrodes 123 extend to the interconnection regions 14, that is, the connection lines connected to the top electrodes 123 extend to the interconnection regions 14, so as to be connected to the bottom electrodes 121.

The plurality of piezoelectric layers 122 are separated in the interconnection regions 14. To connect the bottom electrodes 121 to the top electrodes 123, a metal material of the top electrodes 123 is deposited into the interconnection regions 14 and is connected to the adjacent bottom electrodes 121 to achieve the connection between the top electrodes 123 and the bottom electrodes 121.

When the plurality of piezoelectric layers 122 are separated in the interconnection regions, a ring groove that surrounds the piezoelectric layer 122 is formed on an outer side of each piezoelectric layer 122. The ring slot is filled with air. The acoustic impedance of the piezoelectric layers 122 is different from that of the air, so that an acoustical reflection structure is formed by the ring slots at peripheries of the piezoelectric layers 122. This acoustical reflection structure may reflect sound waves generated at the peripheries of the piezoelectric layers 122 back into the piezoelectric layers 122, further avoiding the leakage of the sound waves from edges of the piezoelectric layers 122, thereby further improving the quality factor of the bulk acoustic wave resonator 100.

In some embodiments, as shown in FIG. 1 and FIG. 2, the top electrodes 123 of the two target resonance assemblies are connected and the connection line of the top electrodes 123 is led out to one side of the determinant, and the bottom electrodes 121 of the two target resonance assemblies are connected and the connection line of the bottom electrodes 121 is led out to an opposite side to the one side of the determinant.

The top electrodes 123 of the two target resonance assemblies are connected and led out to one side of the determinant, that is, the input end 131 is arranged on one side of the determinant. The bottom electrodes 121 of the two target resonance assemblies are connected and led out to the opposite side of the determinant, that is, the output end 132 is arranged on the other side of the determinant, so that the input end 131 and output end 132 are located at the two opposite ends of the determinant, which facilitates the layout of the input end 131 and the output end 132 and avoids the mutual influence caused by a short distance between the input end 131 and output end 132.

In an implementation of this embodiment of the present application, as shown in FIG. 3, a seed layer 15 is further arranged on the substrate 11, and the plurality of resonance assemblies 12 are arranged on the substrate 11 through the seed layer 15.

In order to improve the stability of crystal structures of the bottom electrodes 121 and the piezoelectric layers 122, the seed layer 15 is first formed on the substrate 11 before the bottom electrodes 121 are formed. The seed layer 15 serves as a nucleation center to guide the subsequent generation of the bottom electrodes 121 and the piezoelectric layers 122, so that the crystal structures of the bottom electrodes 121 and the piezoelectric layers 122 are more regular, thereby improving the transmission efficiency of the bottom electrodes 121 and the electro-mechanical conversion efficiency of the piezoelectric layers 122.

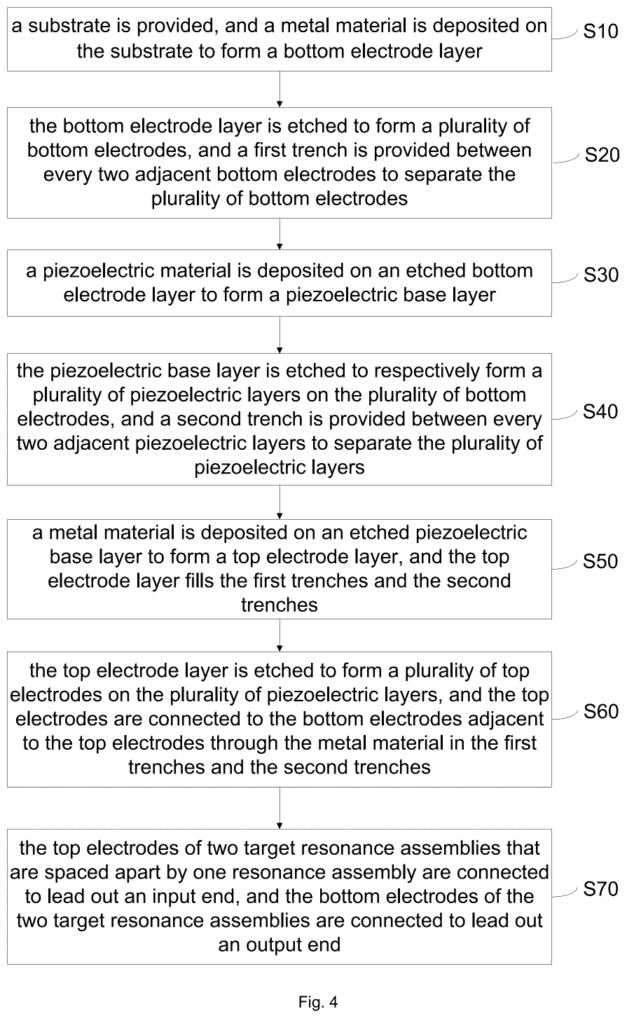

An embodiment of the present application further provides a method for manufacturing a bulk acoustic wave resonator 100, which is used for manufacturing the bulk acoustic wave resonator 100 described above, as shown in FIG. 4, including:
S10: a substrate 11 is provided, and a metal material is deposited on the substrate 11 to form a bottom electrode layer;
A specific material of the substrate 11 and a specific material of the metal material are not limited in this embodiment of the present application, and a substrate 11 and electrode materials which are commonly used in a resonator may be used.
S20: the bottom electrode layer is etched to form a plurality of bottom electrodes, and a first trench is provided between every two adjacent bottom electrodes to separate the plurality of bottom electrodes;
S30: a piezoelectric material is deposited on an etched bottom electrode layer to form a piezoelectric base layer;
S40: the piezoelectric base layer is etched to respectively form a plurality of piezoelectric layers 122 on the plurality of bottom electrodes, and a second trench is provided between every two adjacent piezoelectric layers 122 to separate the plurality of piezoelectric layers 122;
S50: a metal material is deposited on an etched piezoelectric base layer to form a top electrode layer, and the top electrode layer fills the first trenches and the second trenches;
S60: the top electrode layer is etched to form a plurality of top electrodes 123 on the plurality of piezoelectric layers 122, and the top electrodes 123 are connected to the bottom electrodes adjacent to the top electrodes through the metal material in the first trenches and the second trenches;
S70: the top electrodes 123 of two target resonance assemblies 12 that are spaced apart by one resonance assembly 12 are connected to lead out an input end 131, and the bottom electrodes of the two target resonance assemblies 12 are connected to lead out an output end 132.

It should be noted that the first trench and the second trench may also be formed in the same step, that is, the piezoelectric material is deposited on the bottom electrode layer before the bottom electrode layer is etched, and the first trench and the second trench may be formed in one etching.

The bulk acoustic wave resonator 100 manufactured by the method for manufacturing the bulk acoustic wave resonator 100 provided by the embodiments of the present application may improve the effect of second harmonics suppression on the basis of not increasing the volume of the bulk acoustic wave resonator 100.

An embodiment of the present application further provides a method for manufacturing a bulk acoustic wave resonator 100, which is used for manufacturing the bulk acoustic wave resonator 100 described above, as shown in FIG. 1 and FIG. 3, including:
Step S11: a substrate 11 is provided, and a plurality of bottom electrodes 121 are formed on the substrate 11, and two adjacent bottom electrodes 121 are separated;
A specific material of the substrate 11 is not limited in this embodiment of the present application, and a substrate 11 which is commonly used in a resonator may be used.
Step S21: a piezoelectric layer 122 is formed on each of the plurality of bottom electrodes 121, and two adjacent piezoelectric layers 122 are separated;
Step S31: a top electrode 123 is formed on each of the piezoelectric layers 122, and each top electrode 123 is connected to the bottom electrode 121 adjacent to the top electrode;
Step S41: the top electrodes 123 of two target resonance assemblies are connected to lead out an input end 131; and the bottom electrodes 121 of the two target resonance assemblies are connected to lead out an output end 132, and two resonance assemblies 12 spaced apart by one resonance assembly 12 are the two target resonance assemblies; each of the resonance assemblies 12 includes the bottom electrode 121, the piezoelectric layer 122, and the top electrode 123.

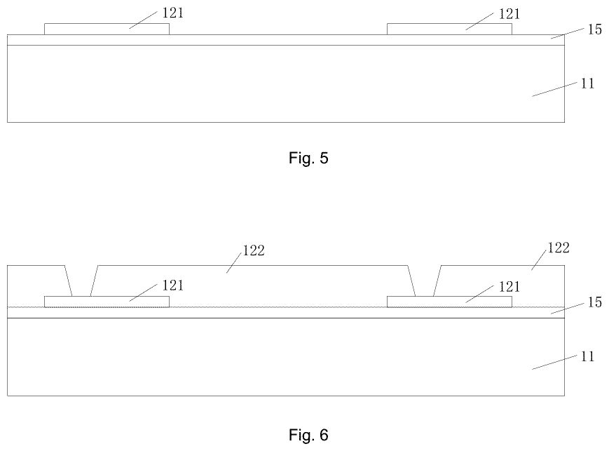

Further, as shown in FIG. 5, the plurality of bottom electrodes 121 are formed on the substrate 11, which includes:
a metal material is deposited on the substrate 11 to form a bottom electrode layer; and
the bottom electrode layer is etched to form the plurality of bottom electrodes 121, and a first trench is provided between every two adjacent bottom electrodes 121 to separate the plurality of bottom electrodes 121.

As shown in FIG. 6, the piezoelectric layer 122 is formed on each of the plurality of bottom electrodes 121, which includes:
a piezoelectric material is deposited on an etched bottom electrode layer to form a piezoelectric base layer; and
the piezoelectric base layer is etched to correspondingly form a plurality of piezoelectric layers 122 on the plurality of bottom electrodes 121, and a second trench is provided between every two adjacent piezoelectric layers 122 to separate the plurality of piezoelectric layers 122.

As shown in FIG. 3, the top electrode 123 is formed on each of the piezoelectric layers 122, which includes:
a metal material is deposited on an etched piezoelectric base layer to form a top electrode layer, and the top electrode layer fills first trenches and second trenches;

A specific material of a specific material of the metal material is not limited in this embodiment of the present application, and electrode materials which are commonly used in a resonator may be used.
the top electrode layer is etched to correspondingly form a plurality of top electrodes 123 on the plurality of piezoelectric layers 122, and each top electrode 123 is connected to the bottom electrode 121 adjacent to the top electrode through the metal material in the first trenches and the second trenches.

The piezoelectric base layer fills first trenches and second trenches. As shown in FIG. 6, the piezoelectric base layer is etched to correspondingly form the plurality of piezoelectric layers 122 on the plurality of bottom electrodes 121, which includes:
the piezoelectric base layer is etched to remove the piezoelectric base layer in the first trenches and the second trenches, and the remaining piezoelectric base layer forms the plurality of piezoelectric layers 122.

The piezoelectric base layer fills the first trenches and the second trenches. The piezoelectric base layer is etched to correspondingly form the plurality of piezoelectric layers 122 on the plurality of bottom electrodes 121, which includes:
the piezoelectric base layer is etched to remove the piezoelectric base layer in the first trenches and the second trenches to form the plurality of piezoelectric layers 122, and through grooves that expose the bottom electrodes 121 are formed in the first trenches and the second trenches.

In addition, as shown in FIG. 5, the substrate 11 is provided, and the plurality of bottom electrodes 121 are formed on the substrate 11, which includes:
the substrate 11 is provided;
a seed layer 15 is formed on the substrate 11; and
the plurality of bottom electrodes 121 separated from each other are formed on the seed layer 15.

The above descriptions are only preferred embodiments of the present application, and are not intended to limit the present application. For those skilled in the art, the present application may have various modifications and changes. Any modification, equivalent replacement, and improvement made within the spirit and scope of the present application shall fall within the protection scope of the present application.

What is claimed is:

1. A bulk acoustic wave resonator, comprising a substrate and a plurality of resonance assemblies arranged on the substrate, wherein each of the plurality of resonance assemblies comprises a bottom electrode, a piezoelectric layer, and a top electrode which are arranged on the substrate in sequence; the plurality of resonance assemblies are connected in sequence to form a connecting ring; the top electrode of one resonance assembly in two adjacent resonance assemblies is connected to the bottom electrode of the other resonance assembly in the two adjacent resonance assemblies; two resonance assemblies spaced apart by one resonance assembly are two target resonance assemblies; top electrodes of the two target resonance assemblies are connected to each other to transmit an input signal; and bottom electrodes of the two target resonance assemblies are connected to each other to transmit an output signal.

2. The bulk acoustic wave resonator as claimed in claim 1, wherein the bulk acoustic wave resonator comprises four resonance assemblies; and the four resonance assemblies are connected in sequence through top electrodes and bottom electrodes to form the connecting ring.

3. The bulk acoustic wave resonator as claimed in claim 2, wherein the four resonance assemblies are arranged in a determinant manner on the substrate.

4. The bulk acoustic wave resonator as claimed in claim 3, wherein an interconnection region is formed between every two adjacent resonance assemblies, and the top electrode of one resonance assembly in the every two adjacent resonance assemblies and the bottom electrode of the other resonance assembly in the every two adjacent resonance assemblies are connected in the interconnection region.

5. The bulk acoustic wave resonator as claimed in claim 4, wherein a plurality of piezoelectric layers are connected in interconnection regions; at least one through groove is formed in the piezoelectric layer in each interconnection region to form a connection region; and at least one of the following is satisfied: the bottom electrode extend into the through groove, so as to be connected to the top electrode, and the top electrode extend into the through groove, so as to be connected to the bottom electrode.

6. The bulk acoustic wave resonator as claimed in claim 5, wherein a cross section of each through groove in a stacking direction is in one shape of a polygon, a circle, and a pattern formed by combining a plurality of curved edges.

7. The bulk acoustic wave resonator as claimed in claim 4, wherein a plurality of piezoelectric layers are separated in interconnection regions, and at least one of the following is satisfied: the bottom electrode extends to the interconnection region, so as to be connected to the top electrode, and the top electrode extends to the interconnection region, so as to be connected to the bottom electrode.

8. The bulk acoustic wave resonator as claimed in claim 3, wherein the top electrodes of the two target resonance assemblies are connected and led out to one side of the determinant, and the bottom electrodes of the two target resonance assemblies are connected and led out to an opposite side to the one side of the determinant.

9. The bulk acoustic wave resonator as claimed in claim 1, wherein a seed layer is further arranged on the substrate, and the plurality of resonance assemblies are arranged on the substrate through the seed layer.

10. The bulk acoustic wave resonator as claimed in claim 1, wherein a region where the bottom electrode, the piezoelectric layer, and the top electrode of each resonance assembly overlap is a resonance region, and a shape of the resonance region is one of the following: a regular polygon, an irregular polygon, a circle, and a closed pattern formed by a plurality of curved edges.

11. The bulk acoustic wave resonator as claimed in claim 3, wherein among the four resonance assemblies, the two target resonance assemblies are centrosymmetric.

12. The bulk acoustic wave resonator as claimed in claim 2, wherein the four resonance assemblies form a balancing bridge structure.

13. A method for manufacturing a bulk acoustic wave resonator, which is used for manufacturing the bulk acoustic wave resonator as claimed in claim 1, comprising:
providing a substrate, and forming a plurality of bottom electrodes on the substrate, wherein two adjacent bottom electrodes are separated;
forming a piezoelectric layer on each of the plurality of bottom electrodes, wherein two adjacent piezoelectric layers are separated;
forming a top electrode on each of the piezoelectric layers, wherein each top electrode is connected to the bottom electrode adjacent to the top electrode; and
connecting the top electrodes of two target resonance assemblies to lead out an input end, and connecting the bottom electrodes of the two target resonance assemblies to lead out an output end, wherein two resonance assemblies spaced apart by one resonance assembly are the two target resonance assemblies, each of the resonance assemblies comprises the bottom electrode, the piezoelectric layer, and the top electrode.

14. The method as claimed in claim 13, wherein forming the plurality of bottom electrodes on the substrate comprises:
depositing a metal material on the substrate to form a bottom electrode layer; and
etching the bottom electrode layer to form the plurality of bottom electrodes, wherein a first trench is provided between every two adjacent bottom electrodes to separate the plurality of bottom electrodes.

15. The method as claimed in claim 14, wherein forming the piezoelectric layer on each of the plurality of bottom electrodes comprises:
depositing a piezoelectric material on an etched bottom electrode layer to form a piezoelectric base layer; and
etching the piezoelectric base layer to correspondingly form a plurality of piezoelectric layers on the plurality of bottom electrodes, wherein a second trench is provided between every two adjacent piezoelectric layers to separate the plurality of piezoelectric layers.

16. The method as claimed in claim 15, wherein forming the top electrode on each of the piezoelectric layers comprises:
depositing a metal material on an etched piezoelectric base layer to form a top electrode layer, wherein the top electrode layer fills first trenches and second trenches; and
etching the top electrode layer to correspondingly form a plurality of top electrodes on the plurality of piezoelectric layers, wherein each top electrode is connected to the bottom electrode adjacent to the top electrode through the metal material in the first trenches and the second trenches.

17. The method as claimed in claim 15, wherein the piezoelectric base layer fills first trenches and second trenches; and etching the piezoelectric base layer to correspondingly form the plurality of piezoelectric layers on the plurality of bottom electrodes comprises:
etching the piezoelectric base layer to remove the piezoelectric base layer in the first trenches and the second trenches, wherein a remaining piezoelectric base layer forms the plurality of piezoelectric layers.

18. The method as claimed in claim 13, wherein providing the substrate, and forming the plurality of bottom electrodes on the substrate comprises:
providing the substrate;
forming a seed layer on the substrate; and
forming the plurality of bottom electrodes separated from each other on the seed layer.
